(19) United States
(12) Patent Application Publication
(10) Pub. No.: US 2007/0136631 A1
(43) Pub. Date: Jun. 14, 2007

(54) Method and system for testing backplanes utilizing a boundary scan protocol

(76) Inventors: Atul V. Govani, Sterling, VA (US); Gerald A. Talen, Bethesda, MD (US)

Correspondence Address: THE SMALL PATENT LAW GROUP LLP, 611 OLIVE STREET, SUITE1611, ST. LOUIS, MO, 63101, US

(21) Appl. No.: 11/351,915

(22) Filed: Feb. 10, 2006

Related U.S. Application Data
(60) Provisional application No. 60/738,348, filed on Nov. 19, 2005.

(51) Int. Cl. G01R 31/28; G06F 11/00

(52) U.S. Cl. 714/738

(57) ABSTRACT

A system is provided for testing connectivity of a backplane having card slots with multiple nets in each card slot. The system includes a processor module that generates test vectors based on a net connectivity configuration for a predetermined backplane architecture. A master control card includes a card slot interconnect that is configured to be plugged into nets in the backplane. The master control card communicates over a serial interface with the processor module. The master control card receives the test vectors, associated with multiple card slots, over the serial interface. The master control card is configured to test the connectivity of the backplane based on the test vectors. Optionally, IOB test cards may be included that each have a card slot interconnect that is configured to be plugged into nets in a respective card slot of the backplane. The IOB test cards are joined in series with the master control card and with one another. Optionally, the test vectors may be defined based on an IEEE 1149.1 boundary scan test protocol.

### RELATED APPLICATION

The present application relates to and claims priority from Provisional Application Ser. No. 60/738,348, filed Nov. 19, 2005, titled “METHOD AND SYSTEM FOR TESTING BACKPLANES UTILIZING A BOUNDARY SCAN PROTOCOL”, the complete subject matter of which is hereby expressly incorporated by reference in its entirety.

### BACKGROUND OF THE INVENTION

The present invention generally relates to methods and systems for testing backplanes utilizing a boundary scan protocol.

Backplanes are utilized in a variety of communications and data transfer applications. A backplane is typically provided in a chassis organized into card slots, each of which is configured to receive processor modules, port modules and the like. Each card slot includes at least one interface configured to join with a module inserted therein. The interface includes a configuration of contact receptacles or contact pins (generally referred to as nets). Each module includes a card slot interconnect including one or more connectors having a configuration of contact receptacles or contact pins organized to mate with the corresponding configuration of nets provided in the card slots of the backplane.

During manufacture of a backplane, the nets undergo numerous tests, including connectivity testing. Connectivity testing includes, among other things, testing individual nets for shorts, and testing to ensure individual nets are interconnected in a desired configuration. For example, a backplane architecture may have a net connectivity configuration, in which a net #1 in card slot #1 is joined with a series of nets in card slots #2, #6, and #8. During the connectivity test, it is confirmed that net #1 in card slot #1 is in fact electrically connected to the intended series of nets in card slots #2, #6 and #8. It is also confirmed that net #1 in card slot #1 is not electrically connected to nets, to which it should not be connected.

In the past, connectivity testing has been performed utilizing a “bed of nails” test device. The bed of nails test device grows in complex and becomes more difficult to use as the complexity and overall size of a backplane configuration increases. The bed of nails test device may become unduly complicated.

A need remains for improved methods and systems for testing connectivity of a backplane.

### BRIEF DESCRIPTION OF THE INVENTION

A system is provided for testing connectivity of a backplane having card slots with multiple nets in each card slot. The system includes a processor module that generates test vectors based on a net connectivity configuration for a predetermined backplane architecture. A master control card includes a card slot interconnect that is configured to be plugged into nets in the backplane. The master control card communicates over a serial interface with the processor module. The master control card receives the test vectors, associated with multiple card slots, over the serial interface. The master control card is configured to test the connectivity of the backplane based on the test vectors.

Optionally, IOB test cards may be included that each have a card slot interconnect that is configured to be plugged into nets in a respective card slot of the backplane. The IOB test cards are joined in series with the master control card and with one another. Optionally, the test vectors may be defined based on an IEEE 1149.1 boundary scan test protocol.

### BRIEF DESCRIPTION OF THE DRAWINGS

FIG. 1 illustrates in block diagram of a system for testing connectivity of a backplane formed in accordance with an embodiment of the present invention.

FIG. 2 illustrates a backplane having a series of IOB test cards and master control cards loaded therein in accordance with an embodiment of the present invention.

FIG. 3 illustrates a block diagram of an order in which the master control card and a series of IOB test cards may be interconnected through the backplane during a test procedure.

FIGS. 4A-4B illustrate a block diagram of a master control card formed in accordance with an embodiment of the present invention.

FIG. 5 illustrates a connectivity test procedure performed in accordance with an embodiment of the present invention.

FIGS. 6A-6D illustrate an example of the processing states through which a scan buffer sequences during processing a test vector.

### DETAILED DESCRIPTION OF THE INVENTION

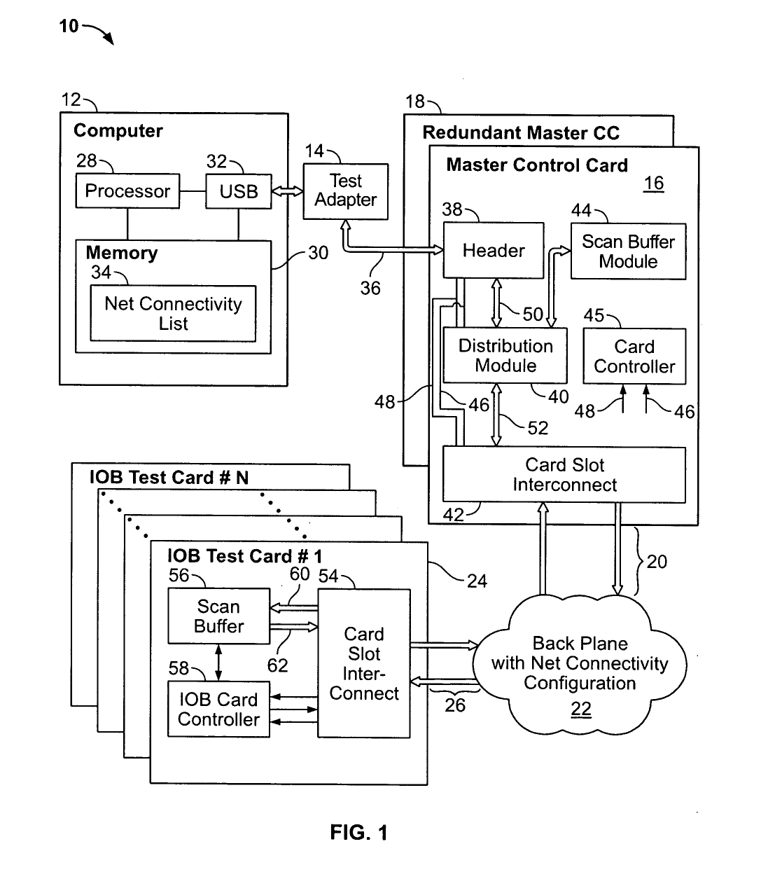

FIG. 1 illustrates a block diagram of a connectivity test system 10 that is provided in accordance with an embodiment of the present invention. The system 10 includes a computer 12 that is joined through a test adapter 14 to one or more master control cards 16. In the example of FIG. 1, a redundant master control card 18 is illustrated, but is not necessary. The master control card 16 is joined at card slot interface 20 to a backplane 22. The backplane 22 includes a series of card slots, each of which includes a series of nets (e.g., contact pins or contact receptacles) interconnected with nets in the same and/or different card slots. The system 10 also includes a series of input/output board (IOB) test cards 24 that are joined to the backplane 22 over card slot interfaces 26. Each IOB test card 24 is constructed similarly and thus only one will be described in detail hereafter.

The computer 12 includes, among other things, a processor module 28, memory 30, and a USB port 32. The memory 30 stores, among other things, files that contain net connectivity lists 34. Each net connectivity list 34 is associated with a particular net connectivity configuration of a backplane 22. The memory 30 may store numerous net connectivity lists 34, one of which is selected once the backplane 22 is constructed. The processor module 28 identifies a desired net connectivity list 34, and calculates there from, test vectors to be utilized by the master control card 16 and IOB test cards 24 to test the connectivity of the nets in the backplane 22. The test vectors are calculated based on a boundary scan protocol defined in IEEE standard 1149.1. Each test vector may represent a vector comprising a series of data bit values, referred to as test data in (TDI) that are sent as source signals over select nets. Once test vectors are calculated for a backplane 22 by the processor module 28 based a desired net connectivity list 34, the test vectors are conveyed through the USB port 32 to the test adapter 44. The test adapter 44 converts the format of the incoming test vectors from a USB compatible format to the format defined within the IEEE 1149.1 protocol.

The test vectors are routed over link 36 to a header 38 within the master control card 16. The header 38 operates as a bidirectional interface with the test adapter 14 to manage incoming test vectors and outgoing data samples. The test vectors from the adapter 14 may include, in addition to the test vectors, a test mode select (TMS) signal, a test clock (TCLK) signal, and a test reset (TRST) signal. The TMS signal indicates the test mode for the corresponding test vector. The TCLK signal is used to capture the test data in (TDI) and test data out (TDO) signals in the scan converters. Each test vector is comprised of a series of positions or individual TDI signals having a logic high level or a logic low level. For example, each TDI signal may be advanced at the leading edge of the TCLK signal, while the TDO signals may be captured at the trailing edge of the TCLK signal. A series of TDO signals form a response vector.

The header 38 separates, from the link 36, test data inputs (as test vectors), the TMS signal 46, the TCLK signal 48 and the TRST signal. The test vectors are passed over link 50 from the header 38 to a distribution module 40. The TMS signal 46 and TCLK signal 48 are passed to the distribution module 40 as well for routing through the backplane 22. The distribution module 40 is bidirectionally joined to a card slot interconnect 42 which in turn is plugged into the backplane 22 through the card slot interface 20. The distribution module 40 routes individual TDI signals (e.g., logic high or logic low levels) within the test vector to predetermined IOB test cards 24 (e.g., registers in scan buffers) of the backplane 22. The TDI signals are applied as source signals to corresponding pins on each IOB test cards 24. The TDI signals are conveyed from the source pin over one or more nets to one or more destination pins interconnected with the source pin.

A scan buffer module 44 includes multiple scan buffers that temporarily store TDI signals and TDO signals. The scan buffer module 44 is joined through the distribution module 40 to the card slot interconnect 42. The distribution module 40 subsequently routes outgoing TDO samples to the header 38, which in turn routes the TDO samples to the test adapter 14 over link 36. A card controller 45 may be included that receives the TMS signal 46 and TCLK signal 48. The card controller 45 controls operation of the scan buffer 44 based on the TMS and TCLK signals 46 and 48. Optionally, the card controller 45 may be omitted and the scan buffer 44 constructed to operate directly based on the TMS and TCLK signals 46 and 48.

Each IOB test card 24 includes a card slot interconnect 54, scan buffers 56 and an IOB card controller 58. The IOB card controller 58 controls the operation of the scan buffers 56 based on TMS and TCLK signals. Each IOB test card 24 may include one or more scan buffers 56. The scan buffers 56 collectively store a test vector as TDI signals in individual registers. The card slot interconnect 54 receives, over link 26, the test vectors, TMS 46 and TCLK 48. The TMS 46 and TCLK 48 are passed to the IOB card controller 58, while the test vector is passed over TDI link 60 to the scan buffer 56. Under the control of the IOB card controller 58, the scan buffer 56 records test data out (TDO) signals from the card slot interconnect 54 for corresponding nets of the backplane 22. The TDO signals collectively form a response vector. The scan buffer 56 then outputs the response vector over TDO link 62 back to the card slot interconnect 54.

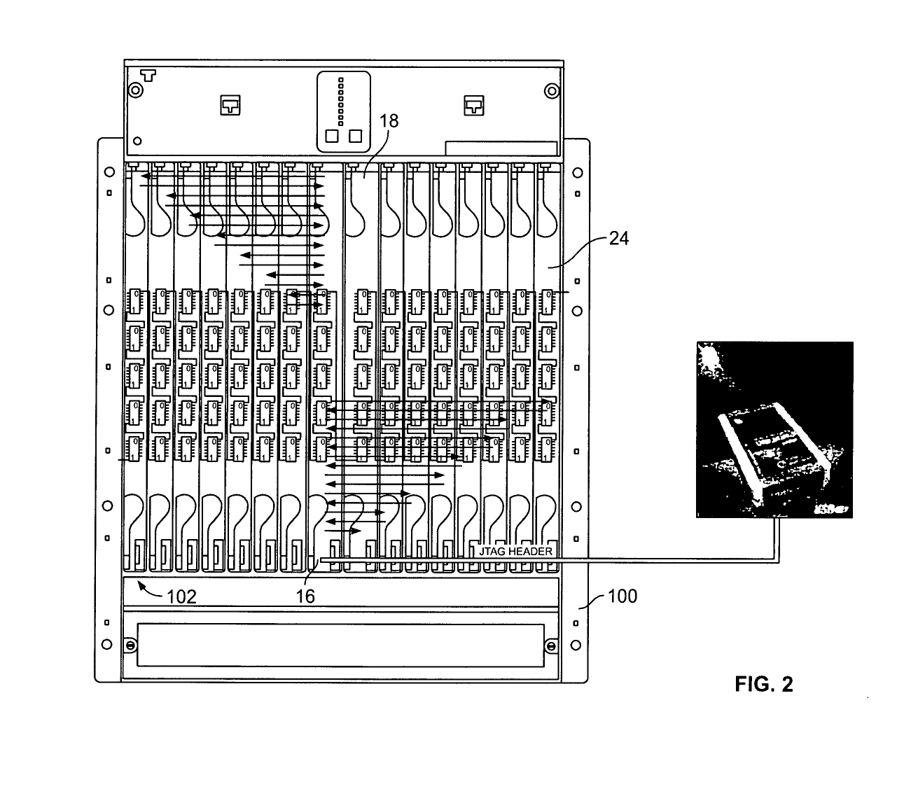

FIG. 2 illustrates a backplane 100 loaded with multiple IOB test cards 24, a master control card 16 and a redundant master control card 18. The backplane 100 includes multiple card slots 102, each of which includes a configuration of contact pins or contact receptacles to which the IOB test cards 24, master control card 16 and redundant master control card 18 are interconnected.

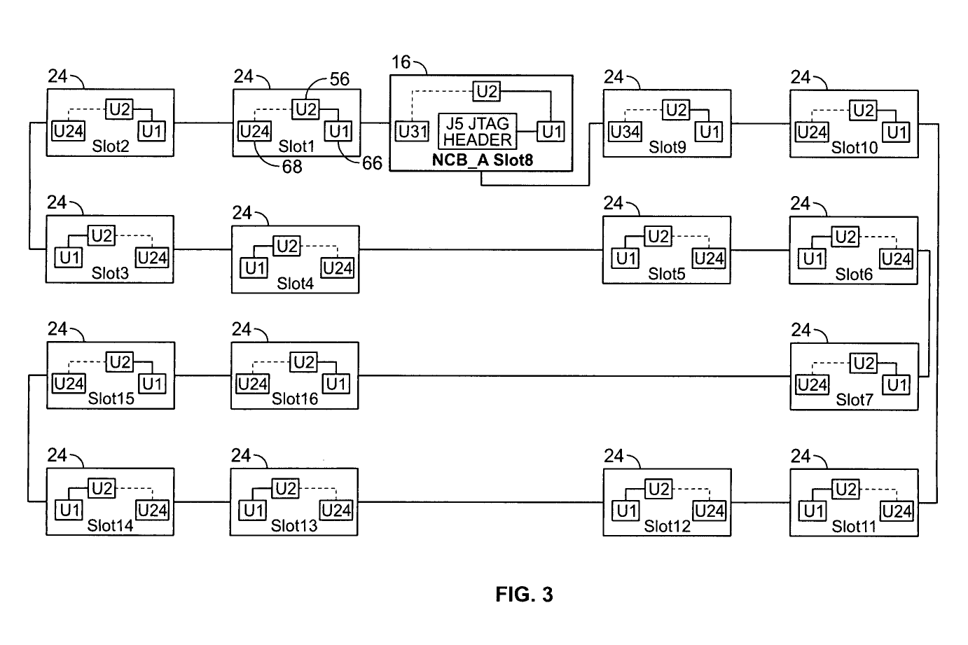

FIG. 3 illustrates an exemplary configuration in which the master control card 16 may be interconnected with the IOB test cards 24. As shown in FIG. 3, the IOB test cards 24 are connected in series. In FIG. 3, each IOB test card 24 is labeled with a slot number denoting the slot within the backplane 100, in which the IOB test card 24 is loaded. For purposes of illustration, each IOB test card 24 is shown to include an input connector 66, an output connector 68 and the scan buffer 56 there between.

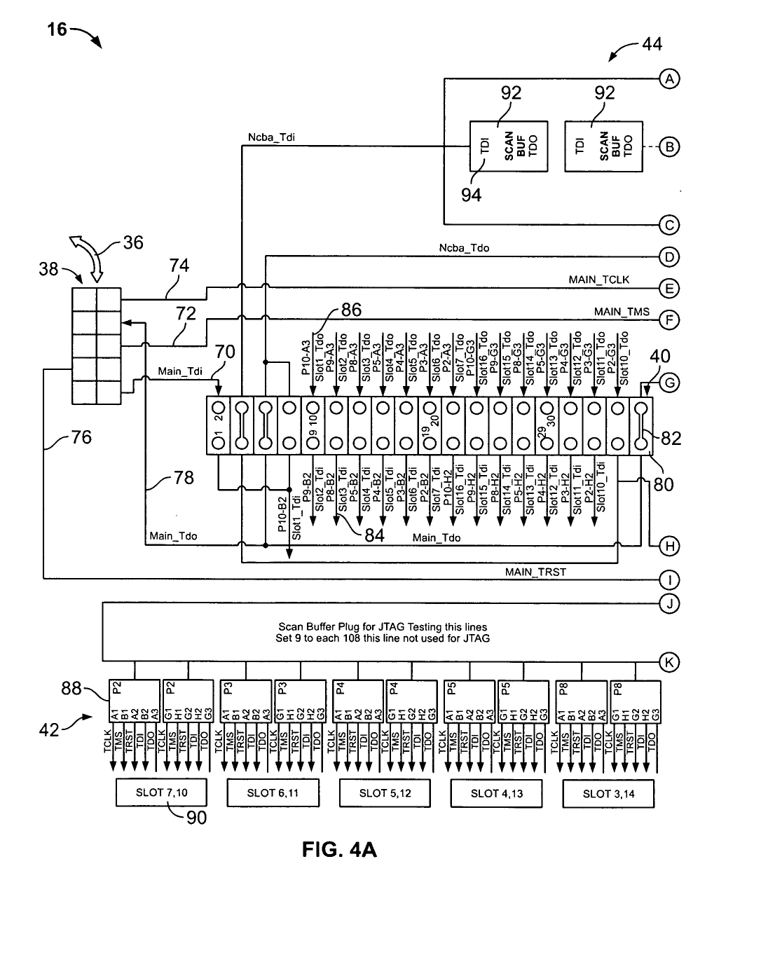

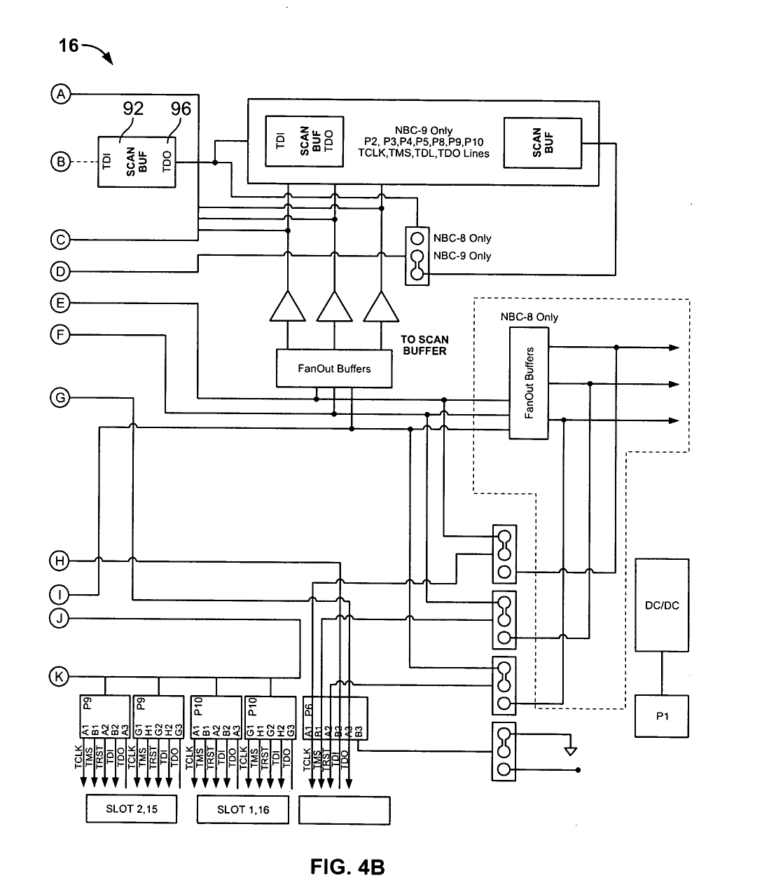

FIGS. 4A-4B illustrate a detailed block diagram of the master control card 16. As shown in FIG. 4A-4B, the header 38 receives information over link 36 and separates the incoming information into test data which are conveyed over the main TDI channel 70, a main TMS channel 72, a main TCLK channel 74 and a main TRST channel 76. A main TDO channel 78 is provided to the header 38 to be transmitted back over link 36 to the adapter 14 (FIG. 1). The distribution module 40 is formed as a series of connection blocks 80 having jumpers 82 provided therein in a predetermined configuration corresponding to the test vectors calculated by the computer 12. Each block 80 has an outbound signal 84 and an inbounds signal 86 joined to corresponding pins at the card slot interconnect 42. In the example of FIG. 4, the outbound and inbound signals 84 and 86 are labeled to illustrate exemplary slots, connectors and pins to which each TDI and TDO signal is directed.

The card slot interconnect 42 includes a series of connectors 88, each having a P# designation. Each connector 88 includes individual contacts labeled A1, B1, A2, B2, etc. In the example of FIG. 4, slot labels 90 are included to illustrate the slots to which corresponding connectors are joined. Scan buffer 44 is shown to include a series of scan buffers 92, each of which has TDI inputs 94 and TDO outputs 96.

Optionally, the master control card 16 and/or redundant master control card 18 may be operated simply with the functionality of the IOB test cards 24.

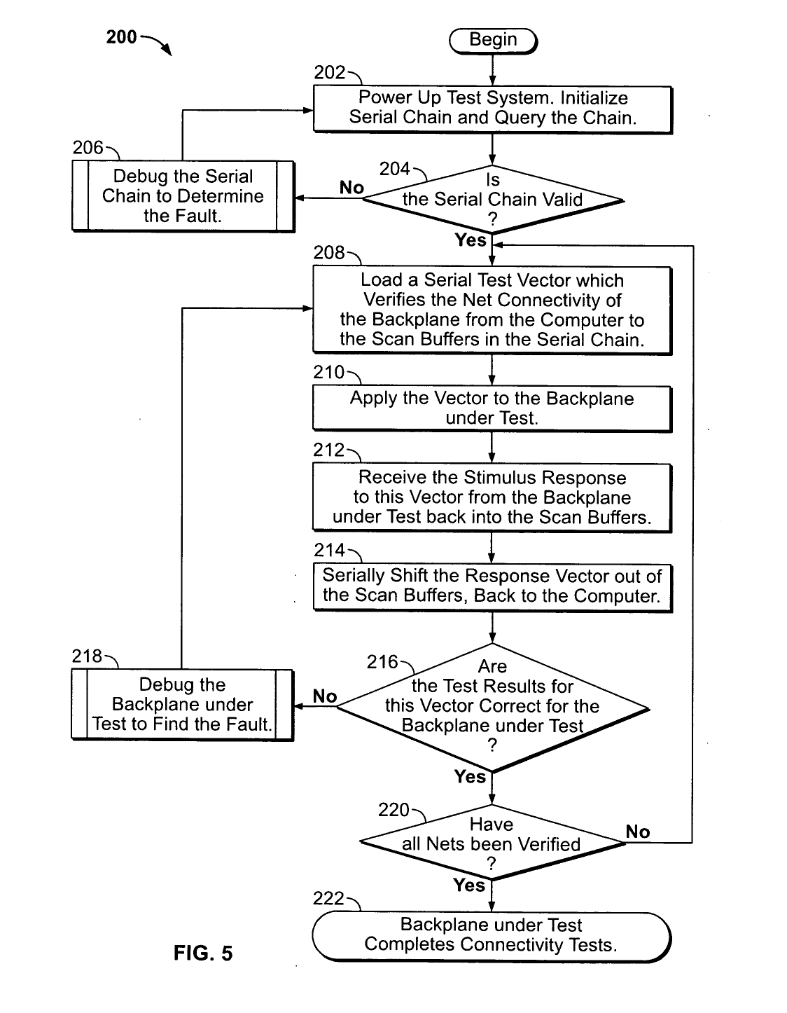

FIG. 5 illustrates a connectivity test procedure 200 performed in accordance with an embodiment of the present invention. At 202, the system 10 is powered up, and the computer 12 initializes the serial chain that includes the IOB test cards 24, master control card 16, the redundant master control card 18 and the like. Also, at 202 the computer 12 queries the components by conveying ID codes to each component and confirmed that a correct reply message is received. At 204 the computer 12 determines whether the serial chain is valid. If the serial chain is not valid, flow passes to 206 where a technician is provided with information regarding a fault in the serial chain. The technician then debugs the serial chain at 206.

At 204, if the serial chain is valid, flow passes to 208. The computer 12 accesses memory 30 to obtain the net connectivity list 34 associated with the serial chain to be tested. As explained above, the net connectivity list 34 includes a series of test vectors associated with the system 10 and serial chain to be tested. As explained above, each test vector uniquely corresponds to a single net connectivity. The computer 12 operates to sequentially test/verify each net connectivity of the backplane. At 208, the computer 12 determines a net connectivity to be tested and obtains, from memory 30, a test vector associated with the net connectivity.

At 208, the computer 12 loads the test vector into the scan buffers 56 of all of the IOB test cards 24, as well as into the scan buffer 44 in the master control card 16 (and scan buffer in the redundant control card 18). The computer 12 loads the test vector into the scan buffers 56 and 44 through a serial shifting process, such as following the serial chain shown in FIG. 3. At 210, the computer 12 instructs all of the IOB test cards 24 to apply the test vector to the backplane under test. At 212, the computer 12 instructs the IOB test cards 24 to receive stimulus responses from the backplane, and store the stimulus responses as a response vector. The response vector is stored in the corresponding scan buffer 56, 44 of each IOB test card and master control card 16. At 214, the computer 12 instructs the IOB test cards 24 and master control card 16 to serial shift the response vectors out of the scan buffers 56 and 44 along the serial chain to the computer 12. The shift out process is also performed serially following the path shown in FIG. 3. The card controller 45 on the master control card 16 instructs the IOB test cards 24 to perform the operations of 208-214 through the use of the TMS signal 46 and TCLK signal 48.

Once, the computer 12 has received the response vector from the IOB test cards 24, at 206 the computer 12 compares the received response vector with the transmitted test vector. For a net connectivity that has no faults, the response and test vectors will be identical. For a net connectivity with one or more faults, the faults will introduce differences between the response and test vectors. If, at 216, the response vector is determined to include a fault, processing flow moves to 218, where a technician provided with information to debug the net connectivity of the backplane under test. For example, the technician may be provided with card and pin fault information and the type of failure. If, at 216, the response vector is identical to the test vector, then the test results are valid and processing moves to 220. At 220, the computer 12 determines whether additional net connectivity tests remain to be tested. If additional net connectivity tests remain to be tested, flow passes from 220 back to 208 where the computer 12 loads the next test vector. The computer 12 repeats 208-216 until all net connectivity tests of the backplane are completed at 222.

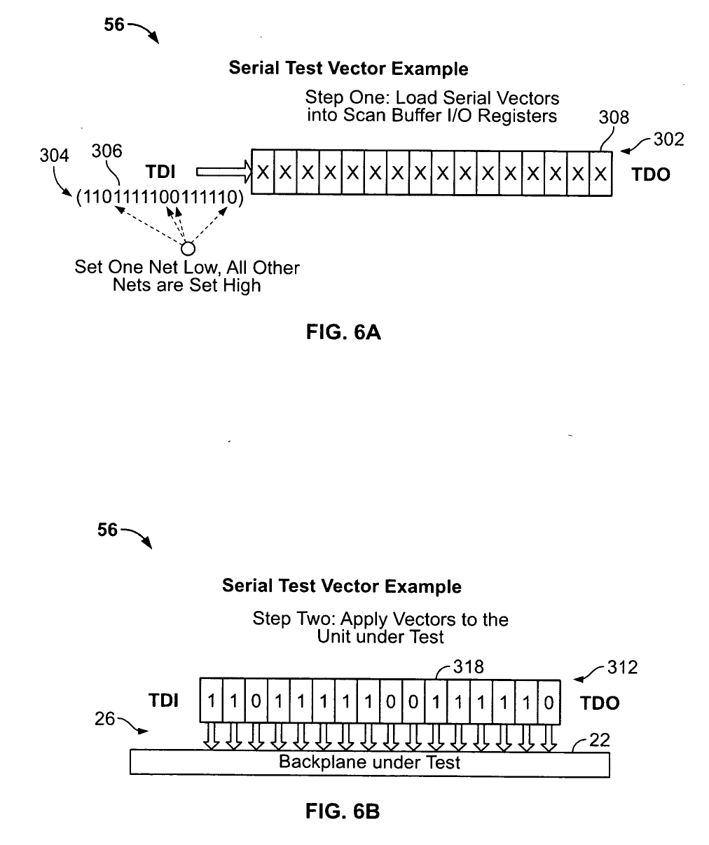

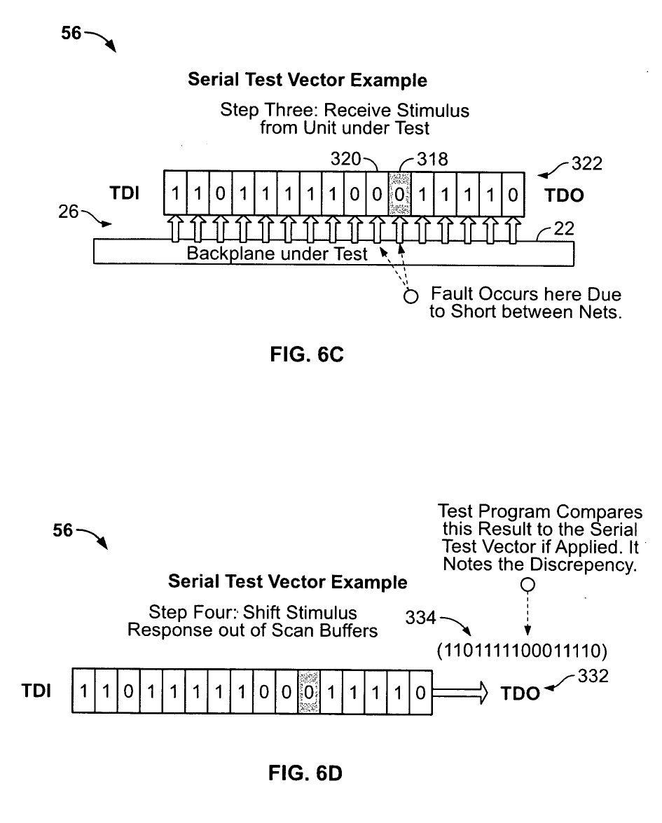

FIGS. 6A-6D illustrate an example of the processing states for a scan buffer 56 during processing a test vector. In FIGS. 6A-6D, a scan buffer 56 is shown at four different states of operation, namely a loading state 302, an application state 312, a receive state 322 and a shift-out state 332. At the loading state 302, the scan buffer 56 loads the test vector 304 over the card slot interface 26. The test vector 304 is loaded serially from the test date in side denoted TDI. The example of FIG. 6 corresponds to a backplane having a single IOB test card 24 and a single scan buffer 56. The scan buffer 56 includes 16 registers 308. The test vector 304 corresponds to a backplane having 16 pins. The test vector 304 includes 16 binary vector positions 306. Each vector position 306 is set to a high logic level (“1”) or a low logic level (“0”) based on the net connectivity to be tested. By way of example, the test vector 304 may be constructed to verify that pin #3 is joined to pins #9, #10 and #16, and is not joined to pins #1-2, #4-8 or #11-15. The vector positions 306 associated with pins #3, #,9, #10 and #16 are set to low states, while the vector positions 306 associated with the remaining pins are set to high states.

When the IOB test card 24 is set to a loading state 302, the scan buffer 56 is loaded serially with the test vector 304 under the control of the TMS and TCLK signals 46 and 48 (see 208 in FIG. 5). Once loaded, each register 308 within the scan buffer 56 stores a corresponding logic level from the test vector 304. Next, the IOB test card 24 is set to an application state 312 and the test vector 304 is applied or used to drive the backplane 22 over the card slot interface 26 (see 210 in FIG. 5). Immediately following the application state 312, the IOB test card 24 is set to a receive state 322 (see 212 in FIG. 5). When in the receive state 322, the scan buffer 56 receives over the card slot interface 26, response stimulus from each of pins #1-#16. Each response stimulus is stored in a corresponding register 308 of the scan buffer 56 for form a response vector. Once the response vector is stored, the IOB test card 24 changes state to a shift-out state 332 (see 214 in FIG. 5). When in the shift-out state, the scan buffer 56 serially shifts the response vector out (as denoted by 334) to the computer 12.

At the application state 312, the scan buffer 56 is shown to include a high logic level in register 318. The signal associate with the high logic level is applied at 312 to the backplane 22. At receive state 322, the scan buffer 56 receives a stimulus signal from the backplane 22 that corresponds to a low logic level in register 318. At 315, the scan buffer 300 stores the stimulus at corresponding registers 316.

In general, when each register 308 applies a signal to the backplane 22, that same register 308 should receive the same signal in return. In the example of FIG. 6, the register 318 receives a low logic level, when the register 318 should have received a high logic level. At shift out state 332, the response vector 334 is shifted out of the scan buffer 56 to the computer 12. The computer 12 then analyzes the response vector 334 with the original test vector 304. The computer 12 identifies the difference corresponding to register 318. The computer 12 determines that an error has occurred that is associated with register 318. In the example of FIG. 6, the error recorded at register 318 corresponds to a short between pins #10 and #11 associated with the registers 318 and 320. The computer 12 informs the technician of the fault at 218 in FIG. 5.

The above process is repeated with multiple different test vectors until every net connectivity is tested. Each test vector corresponds to a single net, where a net represents a network of paths or links from a source pin to one or more destination pins.

In the example of FIG. 6A-6D, a single scan buffer and a single IOB test card are used. It is understood that when multiple IOB test cards and multiple scan buffers are used, the test vector will extend over all of the scan buffers in all of the IOB test cards. Thus, for example, if two IOB test cards were to be tested, when each IOB test card included 8 pins, each scan buffer may have 8 registers. Thus, a 16 position test vector would include 8 positions associated with the scan buffer on the first IOB test card and 8 positions associated with the scan buffer on the second IOB test card. The complete 16 position test vector would be shifted at the loading state 302 until the first 8 positions were stored in the first scan buffer and the second 8 positions were stored in the second scan buffer. Following application of the vector and receipt of the stimulus, the two sets of 8 positions are then shifted out as a 16 position response vector.

While the invention has been described in terms of various specific embodiments, those skilled in the art will recognize that the invention can be practiced with modification within the spirit and scope of the claims.

What is claimed is:

1. A system for testing connectivity of a backplane having card slots with multiple nets in each card slot, the system comprising:
a processor module generating test vectors based on a net connectivity configuration for a predetermined backplane architecture; and
a master control card having a card slot interconnect configured to be plugged into nets in the backplane, the master control card communicating over a serial interface with the processor module, the master control card receiving the test vectors, associated with multiple card slots, over the serial interface, the master control card being configured to test the connectivity of the backplane based on the test vectors.

2. The system of claim 1, further comprising IOB test cards each having a card slot interconnect configured to be plugged into nets in a respective card slot of the backplane, the IOB test cards being joined in series with the master control card and with one another.

3. The system of claim 1, wherein the test vectors are defined based on an IEEE 1149.1 boundary scan test protocol.

4. The system of claim 1, wherein the master control card further comprises a scan buffer, the test vectors being serially shifted through the scan buffer.

5. The system of claim 1, wherein the master control card further comprises distribution module for routing the test vectors through sets of nets.

6. The system of claim 1, further comprising an adaptor located between the processor module and the master control card for converting the test vectors conveyed over the serial link between different first and second data formats.

7. The system of claim 1, further comprising an adaptor located between the processor module and the master control card for converting the test vectors conveyed over the serial link between a USB data format and a data format defined by EEE 1149.1 boundary scan test protocol.

8. The system of claim 1, wherein the processor module is housed in a personal computer.

9. The system of claim 1, further comprising memory storing a net connectivity list identifying an interconnectivity configuration associated with a backplane architecture.

10. A method of testing connectivity of a backplane, the backplane having test cards plugged therein, the method comprising:
generating test vectors based on a net connectivity configuration for a predetermined backplane architecture, the test vectors being based on a boundary scan protocol;
conveying the test vectors over a serial link to test cards plugged into the backplane;
obtaining test data out from the backplane; and
conveying the test data out over the serial link from the test cards.

11. The method of claim 10, wherein the test vectors are defined based on an IEEE 1149.1 boundary scan test protocol.

12. The method of claim 10, wherein the test data out is temporarily stored in a scan buffer on the test card.

13. The method of claim 10, further comprising interconnecting the test cards in series through the backplane.

14. The method of claim 10, wherein conveying includes converting the test vectors over the serial link between different first and second data formats.

15. The method of claim 10, wherein the conveying includes converting the test vectors over the serial link between a USB data format and a data format defined by IEEE 1149.1 boundary scan test protocol.
